(19) United States
(12) Patent Application Publication
(10) Pub. No.: US 2026/0324173 A1
(43) Pub. Date: Oct. 15, 2026

(54) BACKLIGHT MODULE

(71) Applicant: CHICONY POWER TECHNOLOGY CO., LTD., New Taipei City (TW)

(72) Inventors: Shin LIU, New Taipei City (TW); Wen-Yu WU, New Taipei City (TW)

(21) Appl. No.: 19/364,962

(22) Filed: Oct. 21, 2025

(30) Foreign Application Priority Data
Apr. 14, 2025 (TW) 114113998

(51) Int. Cl. H10H 29/855

(52) U.S. Cl. CPC H10H 29/8552

(57) ABSTRACT

A backlight module includes a circuit board, a light guide plate, and a film from bottom to top. The circuit board includes a first light-emitting element and a second light-emitting element. The film sequentially includes a first single-key light transmitting region, a first light shielding region, and a second single-key light transmitting region. The second single-key light transmitting region is located between the first light-emitting element and the second light-emitting element. There is no light-emitting element between the first light-emitting element and the second light-emitting element. The first and second single-key light transmitting regions have a first width. The first light shielding region has a second width. A distance between centers of the first light-emitting element and the second light-emitting element is greater than or equal to a sum of the first and second widths, and less than or equal to twice the sum of the first and second widths.

### BACKGROUND

### Technical Field

The present disclosure relates to a backlight module, in particular to a backlight module applicable to a keyboard.

### Description of Related Art

There are three designs for current keyboard backlight modules. The first design involves disposing at least one light-emitting diode (LED) under each keycap. This design requires a large number of LEDs, resulting in higher costs. The second design involves an LED strip and a light guide plate. The LED strip is disposed perpendicular to a long side of the backlight module and is located in a center of the backlight module. Light emitted by the LED strip is transmitted through the light guide plate to left and right sides of the backlight module. Since a length of the LED strip is approximately the same as a width of the backlight module, this design requires only about 10 to 16 LEDs, which reduces costs. However, since light emitted by the LED strip has a limited transmission distance in the light guide plate, the larger the size of the backlight module, the lower the brightness on the left and right sides of the backlight module. The third design involves disposing an LED strip along a long side of the backlight module, and light emitted by the LED strip is transmitted through the light guide plate to an opposite long side of the backlight module. This design solves an uneven brightness problem of the second design. However, since a length of the LED strip is approximately the same as a length of the backlight module, this design requires about 20 to 30 LEDs, which increases costs. Furthermore, if the backlight module requires heat dissipation, the light guide plate must have more heat dissipation holes. The more heat dissipation holes there are, the more obstructed light transmission will be, and the lower the brightness on the opposite long side of the backlight module will be.

Therefore, how to reduce the number of LEDs while maintaining brightness uniformity is a technical problem that needs to be solved.

### SUMMARY

In order to solve the aforementioned technical problem, the present disclosure provides a backlight module, which includes a circuit board, a light guide plate, and a film. The circuit board includes a first light-emitting element and a second light-emitting element. The light guide plate is disposed on the circuit board, and includes a first through hole and a second through hole. The first light-emitting element is accommodated in the first through hole, and the second light-emitting element is accommodated in the second through hole. The film is disposed on the light guide plate, and includes a first single-key light transmitting region, a second single-key light transmitting region, and a first light shielding region. The first light shielding region is located between the first single-key light transmitting region and the second single-key light transmitting region. The second single-key light transmitting region is located between the first light-emitting element and the second light-emitting element. There is no light-emitting element between the first light-emitting element and the second light-emitting element. The first single-key light transmitting region and the second single-key light transmitting region have a first width in a direction parallel to a long side of the film. The first light shielding region has a second width in the direction. A distance between a center of the first light-emitting element and a center of the second light-emitting element is greater than or equal to a sum of the first width and the second width, and less than or equal to twice the sum of the first width and the second width.

In some embodiments, the film further includes a second light shielding region. The second single-key light transmitting region is located between the first light shielding region and the second light shielding region. The first light-emitting element is disposed corresponding to the first single-key light transmitting region, and the second light-emitting element is disposed corresponding to the second light shielding region.

In some embodiments, the film further includes a third single-key light transmitting region. The second light shielding region is located between the second single-key light transmitting region and the third single-key light transmitting region. The light guide plate includes a first light-guiding region, a second light-guiding region, and a third light-guiding region respectively corresponding to the first single-key light transmitting region, the second single-key light transmitting region, and the third single-key light transmitting region. A microstructure density of the third light-guiding region is greater than a microstructure density of the second light-guiding region, and the microstructure density of the second light-guiding region is greater than a microstructure density of the first light-guiding region.

In some embodiments, the film further includes a second light shielding region. The second single-key light transmitting region is located between the first light shielding region and the second light shielding region. The first light-emitting element is disposed corresponding to the first light shielding region, and the second light-emitting element is disposed corresponding to the second light shielding region.

In some embodiments, the film further includes a third single-key light transmitting region. The second light shielding region is located between the second single-key light transmitting region and the third single-key light transmitting region. The light guide plate includes a first light-guiding region, a second light-guiding region, and a third light-guiding region respectively corresponding to the first single-key light transmitting region, the second single-key light transmitting region, and the third single-key light transmitting region. A microstructure density of the second light-guiding region is less than a microstructure density of the first light-guiding region and a microstructure density of the third light-guiding region, and the microstructure density of the first light-guiding region is substantially equal to the microstructure density of the third light-guiding region.

In some embodiments, the film further includes a second light shielding region and a third single-key light transmitting region. The second single-key light transmitting region is located between the first light shielding region and the second light shielding region. The second light shielding region is located between the second single-key light transmitting region and the third single-key light transmitting region. The first light-emitting element is disposed corresponding to the first single-key light transmitting region, and the second light-emitting element is disposed corresponding to the third single-key light transmitting region.

In some embodiments, the light guide plate includes a first light-guiding region, a second light-guiding region, and a third light-guiding region respectively corresponding to the first single-key light transmitting region, the second single-key light transmitting region, and the third single-key light transmitting region. A microstructure density of the second light-guiding region is greater than a microstructure density of the first light-guiding region and a microstructure density of the third light-guiding region, and the microstructure density of the first light-guiding region is substantially equal to the microstructure density of the third light-guiding region.

In some embodiments, a surface of the film facing the light guide plate is provided with a reflective portion corresponding to the first light-emitting element.

In some embodiments, when a projection of the first light-emitting element on the film is located within the first single-key light transmitting region, the film is further provided with a light-shielding portion located between the reflective portion and the film and corresponding to the first light-emitting element.

In some embodiments, a long side of the first light-emitting element is perpendicular to a long side of the circuit board.

### BRIEF DESCRIPTION OF THE DRAWINGS

FIG. 1 is a schematic diagram of a backlight module according to an embodiment of the present invention.

FIG. 2 is an exploded view of the backlight module in FIG. 1.

FIG. 3 is a partial enlarged view of the backlight module in FIG. 1.

FIG. 4 is another partial enlarged view of the backlight module in FIG. 1.

FIG. 5 is another partial enlarged view of the backlight module in FIG. 1.

FIG. 6 is another partial enlarged view of the backlight module in FIG. 1.

FIG. 7 is another partial enlarged view of the backlight module in FIG. 1.

### DETAILED DESCRIPTION

The embodiments of the present invention will be described clearly and completely below in conjunction with the accompanying drawings. The elements in the accompanying drawings are not drawn to scale and are merely used to illustrate the embodiments of the present invention. The terms such as “first” and “second” mentioned below do not represent any order, quantity, or importance, but are only used to distinguish different parts.

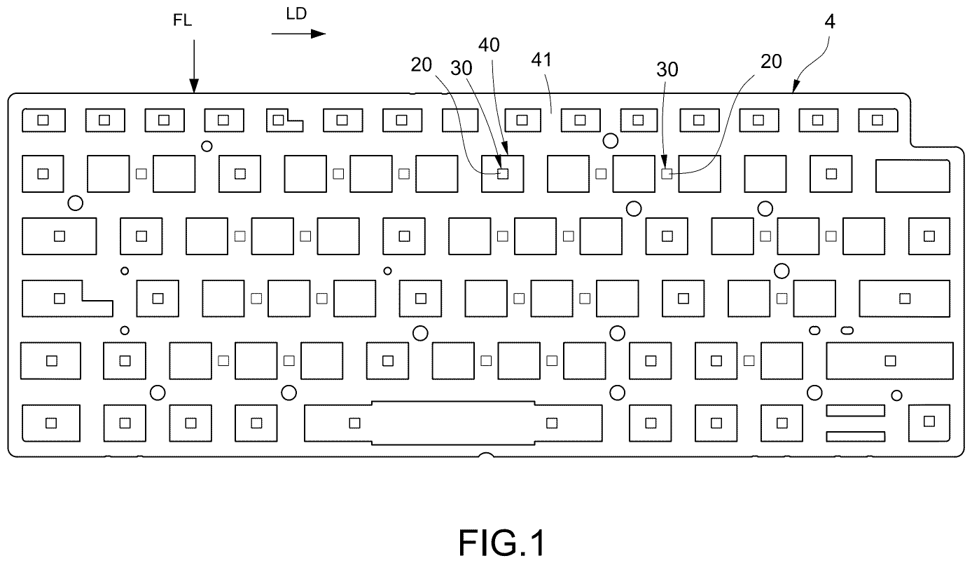

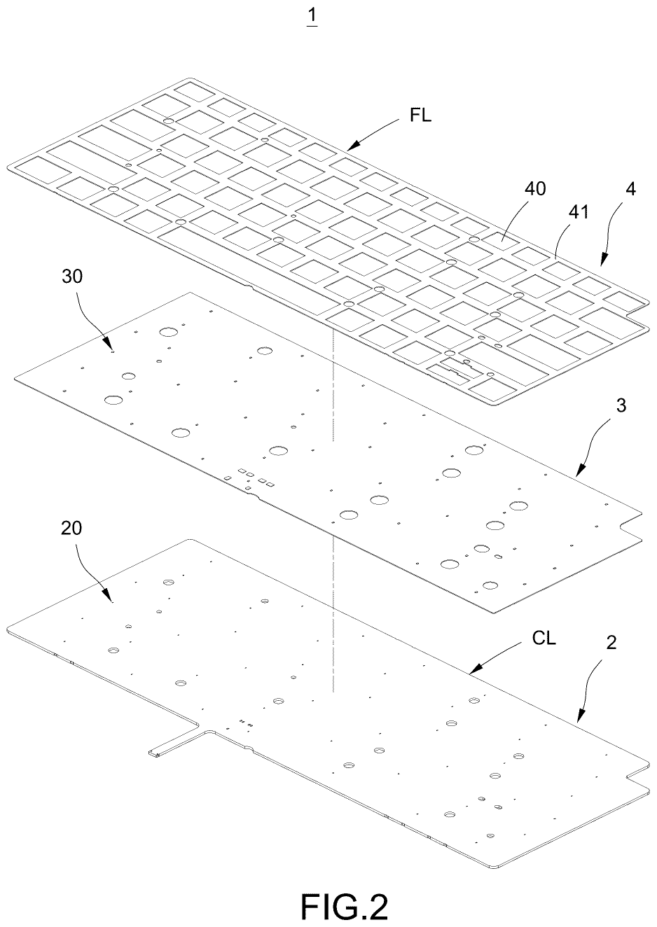

Referring to FIG. 1 and FIG. 2, the present disclosure provides a backlight module 1, which includes a circuit board 2, a light guide plate 3, and a film 4. The circuit board 2 includes a plurality of light-emitting elements 20. The circuit board 2 may be, but is not limited thereto, a flexible circuit board. The light-emitting elements 20 may be light emitting diodes. Specifically, the light-emitting elements 20 may be sub-millimeter light emitting diodes, but are not limited thereto. The light guide plate 3 is disposed on the circuit board 2, and includes a plurality of through holes 30. Each of the through holes 30 is configured to accommodate one of the light-emitting elements 20. The film 4 is disposed on the light guide plate 3, and includes a plurality of single-key light transmitting regions 40 and a light shielding region 41 surrounding the single-key light transmitting regions 40. That is, the single-key light transmitting regions 40 are a plurality of independent regions separated by the light shielding region 41.

Referring to FIG. 1 to FIG. 5, the light-emitting elements 20 include a first light-emitting element 21 and a second light-emitting element 22. The through holes 30 include a first through hole 301 and a second through hole 302. The first light-emitting element 21 is accommodated in the first through hole 301, and the second light-emitting element 22 is accommodated in the second through hole 302. The single-key light transmitting regions 40 include a first single-key light transmitting region 401, a second single-key light transmitting region 402, and a third single-key light transmitting region 403. The light shielding region 41 includes a first light shielding region 411 and a second light shielding region 412. The first light shielding region 411 is located between the first single-key light transmitting region 401 and the second single-key light transmitting region 402. The second single-key light transmitting region 402 is located between the first light shielding region 411 and the second light shielding region 412. The second light shielding region 412 is located between the second single-key light transmitting region 402 and the third single-key light transmitting region 403. That is, the first single-key light transmitting region 401, the first light shielding region 411, the second single-key light transmitting region 402, the second light shielding region 412, and the third single-key light transmitting region 403 are sequentially arranged in a direction LD. The second single-key light transmitting region 402 is located between the first light-emitting element 21 and the second light-emitting element 22. There is no light-emitting element between the first light-emitting element 21 and the second light-emitting element 22. That is, no light-emitting element is required to correspond to the second single-key light transmitting region 402. The first single-key light transmitting region 401, the second single-key light transmitting region 402, and the third single-key light transmitting region 403 have a first width W1 in the direction LD parallel to a long side FL of the film 4. The first light shielding region 411 and the second light shielding region 412 have a second width W2 in the direction LD. A distance D between a center of the first light-emitting element 21 and a center of the second light-emitting element 22 is greater than or equal to a sum of the first width W1 and the second width W2, and less than or equal to twice the sum of the first width W1 and the second width W2. That is, (W1+W2)≤D≤(W1+W2)×2. As long as at least one region of the backlight module 1 includes one or more light-emitting element distribution modes that meet the aforementioned condition, a number of LEDs can be reduced while maintaining brightness uniformity. Furthermore, the larger the region, the greater the reduction in the number of LEDs.

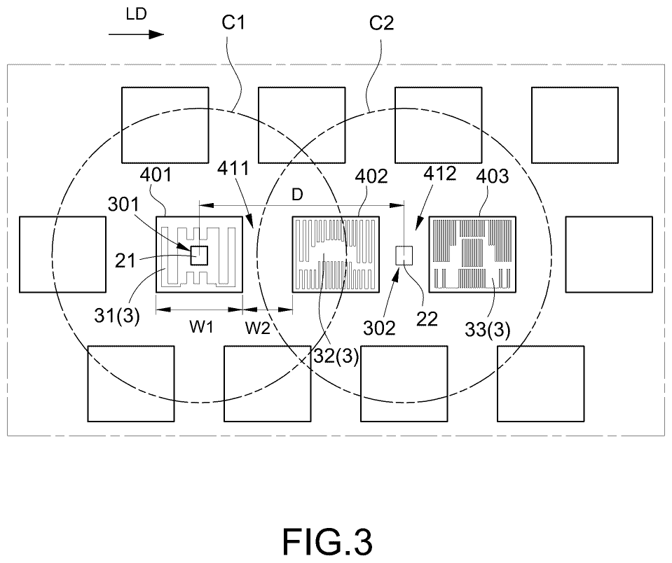

In order to enable those skilled in the art to fully understand the present invention, FIG. 3 to FIG. 5 illustrate three light-emitting element distribution modes that meet the aforementioned condition. FIG. 1 illustrates that a majority of a central region of the backlight module 1 includes the three light-emitting element distribution modes, while each single-key light transmitting region in a majority of a peripheral region of the backlight module 1 is provided with one light-emitting element. FIG. 1 and FIG. 3 to FIG. 5 are not intended to limit the present invention. Those skilled in the art can design various light-emitting element distribution modes in the backlight module 1 under the aforementioned condition, and all of these light-emitting element distribution modes fall within the scope of the present invention.

A first light-emitting element distribution mode of the present disclosure is shown in FIG. 3. The first light-emitting element 21 is disposed corresponding to the first single-key light transmitting region 401, and the second light-emitting element 22 is disposed corresponding to the second light shielding region 412. The distance D between the center of the first light-emitting element 21 and the center of the second light-emitting element 22 is about 1.5 times the sum of the first width W1 and the second width W2. The light guide plate 3 includes a first light-guiding region 31, a second light-guiding region 32, and a third light-guiding region 33 respectively corresponding to the first single-key light transmitting region 401, the second single-key light transmitting region 402, and the third single-key light transmitting region 403. The first light-guiding region 31, the second light-guiding region 32, and the third light-guiding region 33 all have microstructures. The first through hole 301 is located in the first light-guiding region 31. The first light-emitting element 21 is located in the first through hole 301, that is, in the first light-guiding region 31. In this embodiment, the first through hole 301 and the first light-emitting element 21 are located at a center of the first light-guiding region 31, but are not limited thereto. The second through hole 302 is located between the second light-guiding region 32 and the third light-guiding region 33. The second light-emitting element 22 is located in the second through hole 302, that is, between the second light-guiding region 32 and the third light-guiding region 33. In this embodiment, a distance between a center of the second through hole 302 and the second light-guiding region 32 is equal to a distance between the center of the second light-guiding region 32 and the third light-guiding region 33, and a distance between the center of the second light-emitting element 22 and the second light-guiding region 32 is equal to a distance between the center of the second light-emitting element 22 and the third light-guiding region 33, but is not limited thereto. The first light-guiding region 31 is located in a central region of an illumination range C1 of the first light-emitting element 21. The third light-guiding region 33 is located in a right region of an illumination range C2 of the second light-emitting element 22. The second light-guiding region 32 is located in a left region of the illumination range C2 of the second light-emitting element 22, and a part of the second light-guiding region 32 is located in a right region of the illumination range C1 of the first light-emitting element 21. That is, an overlapping portion of the illumination range C1 and the illumination range C2 covers the part of the second light-guiding region 32. Furthermore, a brightness of the illumination range C1 gradually decreases from a center of the illumination range C1 (that is, a location of the first light-emitting element 21) to a periphery of the illumination range C1, and a brightness of the illumination range C2 gradually decreases from a center of the illumination range C2, where the second light-emitting element 22 is located, to a periphery of the illumination range C2. Taking all the above factors into consideration, a microstructure density of the third light-guiding region 33 may be designed to be greater than a microstructure density of the second light-guiding region 32, and the microstructure density of the second light-guiding region 32 may be designed to be greater than a microstructure density of the first light-guiding region 31, so that a brightness of the first light-guiding region 31, a brightness of the second light-guiding region 32, and a brightness of the third light-guiding region 33 are substantially the same. Additionally, considering that the brightness of the illumination range C1 gradually decreases from the center to the periphery of the illumination range C1, the microstructures of the first light-guiding region 31 may be designed to be gradually denser from the center of the first light-guiding region 31 to an edge of the first light-guiding region 31 (not shown), thereby ensuring that all parts of the first light-guiding region 31 have substantially the same brightness. Furthermore, considering that the brightness of the illumination range C2 gradually decreases from the center to the periphery of the illumination range C2, the microstructures of the third light-guiding region 33 may be designed to be gradually denser from a left side to a right side of the third light-guiding region 33 (not shown), thereby ensuring that all parts of the third light-guiding region 33 have substantially the same brightness. Moreover, a microstructure density of each part of the second light-guiding region 32 may be designed by considering whether each part of the second light-guiding region 32 is covered by the illumination range C1 and/or the illumination range C2, as well as a position of each part of the second light-guiding region 32 within the illumination range C1 and/or the illumination range C2, so that all parts of the second light-guiding region 32 have substantially the same brightness.

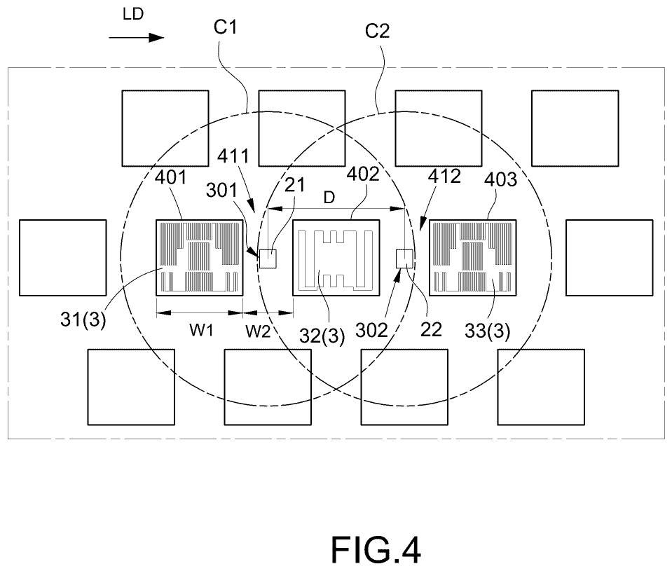

A second light-emitting element distribution mode of the present disclosure is shown in FIG. 4. The first light-emitting element 21 is disposed corresponding to the first light shielding region 411, and the second light-emitting element 22 is disposed corresponding to the second light shielding region 412. The distance D between the center of the first light-emitting element 21 and the center of the second light-emitting element 22 is about equal to the sum of the first width W1 and the second width W2. The light guide plate 3 includes the first light-guiding region 31, the second light-guiding region 32, and the third light-guiding region 33 respectively corresponding to the first single-key light transmitting region 401, the second single-key light transmitting region 402, and the third single-key light transmitting region 403. The first through hole 301 is located between the first light-guiding region 31 and the second light-guiding region 32. The first light-emitting element 21 is located in the first through hole 301, that is, between the first light-guiding region 31 and the second light-guiding region 32. In this embodiment, a distance between a center of the first through hole 301 and the first light-guiding region 31 is equal to a distance between the center of the first through hole 301 and the second light-guiding region 32, and a distance between the center of the first light-emitting element 21 and the first light-guiding region 31 is equal to a distance between the center of the first light-emitting element 21 and the second light-guiding region 32, but is not limited thereto. The second through hole 302 is located between the second light-guiding region 32 and the third light-guiding region 33. The second light-emitting element 22 is located in the second through hole 302, that is, between the second light-guiding region 32 and the third light-guiding region 33. In this embodiment, the distance between the center of the second through hole 302 and the second light-guiding region 32 is equal to the distance between the center of the second through hole 302 and the third light-guiding region 33, and the distance between the center of the second light-emitting element 22 and the second light-guiding region 32 is equal to the distance between the center of the second light-emitting element 22 and the third light-guiding region 33, but is not limited thereto. The first light-guiding region 31 is located in a left region of the illumination range C1 of the first light-emitting element 21. The third light-guiding region 33 is located in the right region of the illumination range C2 of the second light-emitting element 22. The second light-guiding region 32 is located in both the right region of the illumination range C1 and the left region of the illumination range C2. In order to ensure that the brightnesses of the first light-guiding region 31, the second light-guiding region 32, and the third light-guiding region 33 are substantially the same, the microstructure density of the second light-guiding region 32 may be designed to be less than the microstructure density of the first light-guiding region 31 and the microstructure density of the third light-guiding region 33, and the microstructure density of the first light-guiding region 31 may be designed to be substantially equal to the microstructure density of the third light-guiding region 33. Furthermore, the microstructures of the first light-guiding region 31 may be designed to be gradually denser from a right side to a left side of the first light-guiding region 31 (not shown), thereby ensuring that all parts of the first light-guiding region 31 have substantially the same brightness. Moreover, the microstructures of the third light-guiding region 33 may be designed to be gradually denser from the left side to the right side of the third light-guiding region 33 (not shown), thereby ensuring that all parts of the third light-guiding region 33 have substantially the same brightness. Additionally, the microstructure density of each part of the second light-guiding region 32 may be designed by considering the position of each part of the second light-guiding region 32 within the illumination range C1 and/or the illumination range C2, so that all parts of the second light-guiding region 32 have substantially the same brightness.

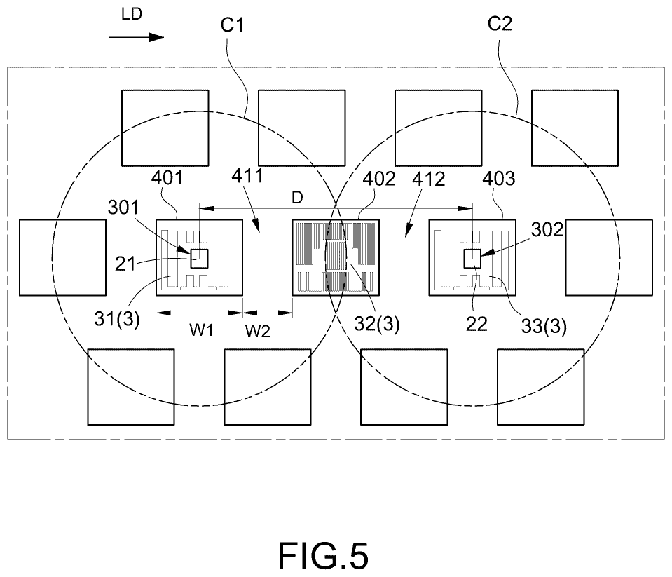

A third light-emitting element distribution mode of the present disclosure is shown in FIG. 5. The first light-emitting element 21 is disposed corresponding to the first single-key light transmitting region 401, and the second light-emitting element 22 is disposed corresponding to the third single-key light transmitting region 403. The distance D between the center of the first light-emitting element 21 and the center of the second light-emitting element 22 is about twice the sum of the first width W1 and the second width W2. The light guide plate 3 includes the first light-guiding region 31, the second light-guiding region 32, and the third light-guiding region 33 respectively corresponding to the first single-key light transmitting region 401, the second single-key light transmitting region 402, and the third single-key light transmitting region 403. The first through hole 301 is located in the first light-guiding region 31. The first light-emitting element 21 is located in the first through hole 301, that is, in the first light-guiding region 31. In this embodiment, the first through hole 301 and the first light-emitting element 21 are located at the center of the first light-guiding region 31, but is not limited thereto. The second through hole 302 is located in the third light-guiding region 33. The second light-emitting element 22 is located in the second through hole 302, that is, in the third light-guiding region 33. In this embodiment, the second through hole 302 and the second light-emitting element 22 are located at a center of the third light-guiding region 33, but are not limited thereto. The first light-guiding region 31 is located in the central region of the illumination range C1 of the first light-emitting element 21. The third light-guiding region 33 is located in a central region of the illumination range C2 of the second light-emitting element 22. The second light-guiding region 32 is partially located in the right region of the illumination range C1 of the first light-emitting element 21, and partially located in the left region of the illumination range C2 of the second light-emitting element 22. The overlapping portion of the illumination range C1 and the illumination range C2 covers a part of the second light-guiding region 32. In order to ensure that the brightnesses of the first light-guiding region 31, the second light-guiding region 32, and the third light-guiding region 33 are substantially the same, the microstructure density of the second light-guiding region 32 may be designed to be greater than the microstructure density of the first light-guiding region 31 and the microstructure density of the third light-guiding region 33, and the microstructure density of the first light-guiding region 31 may be designed to be substantially equal to the microstructure density of the third light-guiding region 33. Furthermore, the microstructures of the first light-guiding region 31 may be designed to be gradually denser from the center to the edge of the first light-guiding region 31 (not shown), thereby ensuring that all parts of the first light-guiding region 31 have substantially the same brightness. Moreover, the microstructures of the third light-guiding region 33 may be designed to be gradually denser from the center to an edge of the third light-guiding region 33 (not shown), thereby ensuring that all parts of the third light-guiding region 33 have substantially the same brightness. Additionally, the microstructure density of each part of the second light-guiding region 32 may be designed by considering the position of each part of the second light-guiding region 32 within the illumination range C1 and/or the illumination range C2, so that all parts of the second light-guiding region 32 have substantially the same brightness.

In any of the light-emitting element distribution modes of the present disclosure, any part of the second single-key light transmitting region 402 is covered by the illumination range C1 of the first light-emitting element 21 and/or the illumination range C2 of the second light-emitting element 22. Therefore, no light-emitting element is required to correspond to the second single-key light transmitting region 402. Accordingly, compared with the related art of disposing at least one LED under each keycap, by adopting any light-emitting element distribution mode of the present disclosure in any area of the backlight module 1 that includes three single-key light transmitting regions 40, at least one LED can be reduced without changing brightness uniformity of the backlight module 1, thereby reducing costs.

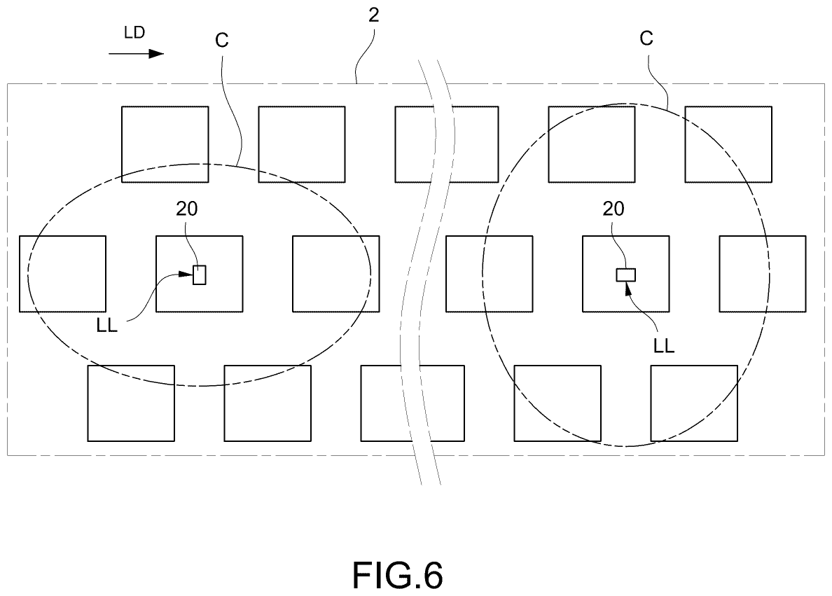

In FIG. 3 to FIG. 5, the illumination range C1 of the first light-emitting element 21 and the illumination range C2 of the second light-emitting element 22 are indicated by dashed circles, but these dashed circles do not represent actual boundaries of the illumination ranges C1 and C2. The dashed circles are merely used to schematically illustrate ranges of lights emitted by the first light-emitting element 21 and the second light-emitting element 22. In addition, depending on types and shapes of the first light-emitting element 21 and the second light-emitting element 22, the illumination ranges C1 and C2 may be other shapes. Referring to FIG. 6, in some embodiments, the light-emitting elements 20 are rectangular, and thus an illumination range C of each of the light-emitting elements 20 is slightly elliptical. Referring to FIG. 1, a number of the single-key light transmitting regions 40 in a row of the single-key light transmitting regions 40 parallel to the long side FL of the film 4 is greater than a number of the single-key light transmitting regions 40 in a column of the single-key light transmitting regions 40. Therefore, compared to a case where a long side LL of the light-emitting element 20 is parallel to a long side Cl of the circuit board 2, a case where the long side LL of the light-emitting element 20 is perpendicular to the long side Cl of the circuit board 2 enables the illumination range C to cover more areas of the single-key light transmitting regions 40 on left and right sides of the light-emitting element 20, thereby improving light utilization efficiency of the light-emitting element 20 (please refer to FIG. 2 and FIG. 6).

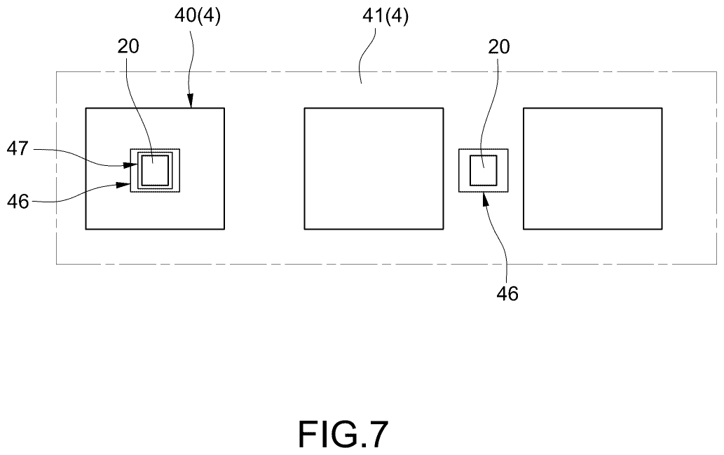

Referring to FIG. 7, in some embodiments, a surface of the film 4 facing the light guide plate 3 is provided with a reflective portion 46. The reflective portion 46 is provided corresponding to the light-emitting element 20 and is configured to reflect a light emitted upward by the light-emitting element 20 to the light guide plate 3, so as to improve the light utilization efficiency and avoid formation of bright spots at the light-emitting element 20. In some embodiments, when a projection of the light-emitting element 20 on the film 4 is located within the single-key light transmitting region 40, the film is further provided with a light-shielding portion 47. The light-shielding portion 47 is located between the reflective portion 46 and the film 4 and corresponds to the light-emitting element 20 to further prevent the formation of bright spots at the light-emitting element 20. An area of the reflective portion 46 may be greater than or equal to an area of the light-shielding portion 47. The light-emitting element 20 may be the first light-emitting element 21 or the second light-emitting element 22.

The embodiments are described in detail above, so that those skilled in the art can fully understand the concept of the present invention. Based on the embodiments, all other embodiments obtained by those skilled in the art without any creative labor shall fall within the scope of the present invention. That is, those skilled in the art may modify the technical solutions in the embodiments, or replace one or more technical features in the embodiments with equivalents. These modifications or equivalent replacements shall fall within the scope of the present invention. Therefore, the scope of the present invention is determined by the appended claims.

What is claimed is:

1. A backlight module, comprising:
a circuit board, comprising a first light-emitting element and a second light-emitting element;
a light guide plate disposed on the circuit board, and comprising a first through hole and a second through hole, wherein the first light-emitting element is accommodated in the first through hole, and the second light-emitting element is accommodated in the second through hole; and
a film disposed on the light guide plate, and comprising a first single-key light transmitting region, a second single-key light transmitting region, and a first light shielding region, wherein the first light shielding region is located between the first single-key light transmitting region and the second single-key light transmitting region, the second single-key light transmitting region is located between the first light-emitting element and the second light-emitting element, and there is no light-emitting element between the first light-emitting element and the second light-emitting element,
wherein the first single-key light transmitting region and the second single-key light transmitting region have a first width in a direction parallel to a long side of the film, the first light shielding region has a second width in the direction, and a distance between a center of the first light-emitting element and a center of the second light-emitting element is greater than or equal to a sum of the first width and the second width and less than or equal to twice the sum of the first width and the second width.

2. The backlight module according to claim 1, wherein the film further comprises a second light shielding region, the second single-key light transmitting region is located between the first light shielding region and the second light shielding region, the first light-emitting element is disposed corresponding to the first single-key light transmitting region, and the second light-emitting element is disposed corresponding to the second light shielding region.

3. The backlight module according to claim 2, wherein the film further comprises a third single-key light transmitting region, the second light shielding region is located between the second single-key light transmitting region and the third single-key light transmitting region, the light guide plate comprises a first light-guiding region, a second light-guiding region, and a third light-guiding region respectively corresponding to the first single-key light transmitting region, the second single-key light transmitting region, and the third single-key light transmitting region, a microstructure density of the third light-guiding region is greater than a microstructure density of the second light-guiding region, and the microstructure density of the second light-guiding region is greater than a microstructure density of the first light-guiding region.

4. The backlight module according to claim 1, wherein the film further comprises a second light shielding region, the second single-key light transmitting region is located between the first light shielding region and the second light shielding region, the first light-emitting element is disposed corresponding to the first light shielding region, and the second light-emitting element is disposed corresponding to the second light shielding region.

5. The backlight module according to claim 4, wherein the film further comprises a third single-key light transmitting region, the second light shielding region is located between the second single-key light transmitting region and the third single-key light transmitting region, the light guide plate comprises a first light-guiding region, a second light-guiding region, and a third light-guiding region respectively corresponding to the first single-key light transmitting region, the second single-key light transmitting region, and the third single-key light transmitting region, a microstructure density of the second light-guiding region is less than a microstructure density of the first light-guiding region and a microstructure density of the third light-guiding region, and the microstructure density of the first light-guiding region is substantially equal to the microstructure density of the third light-guiding region.

6. The backlight module according to claim 1, wherein the film further comprises a second light shielding region and a third single-key light transmitting region, the second single-key light transmitting region is located between the first light shielding region and the second light shielding region, the second light shielding region is located between the second single-key light transmitting region and the third single-key light transmitting region, the first light-emitting element is disposed corresponding to the first single-key light transmitting region, and the second light-emitting element is disposed corresponding to the third single-key light transmitting region.

7. The backlight module according to claim 6, wherein the light guide plate comprises a first light-guiding region, a second light-guiding region, and a third light-guiding region respectively corresponding to the first single-key light transmitting region, the second single-key light transmitting region, and the third single-key light transmitting region, a microstructure density of the second light-guiding region is greater than a microstructure density of the first light-guiding region and a microstructure density of the third light-guiding region, and the microstructure density of the first light-guiding region is substantially equal to the microstructure density of the third light-guiding region.

8. The backlight module according to claim 1, wherein a surface of the film facing the light guide plate is provided with a reflective portion corresponding to the first light-emitting element.

9. The backlight module according to claim 8, wherein when a projection of the first light-emitting element on the film is located within the first single-key light transmitting region, the film is further provided with a light-shielding portion located between the reflective portion and the film and corresponding to the first light-emitting element.

10. The backlight module according to claim 1, wherein a long side of the first light-emitting element is perpendicular to a long side of the circuit board.
